(19) United States
(12) Patent Application Publication
(10) Pub. No.: US 2026/0231840 A1
(43) Pub. Date: Aug. 6, 2026

(54) METHODS FOR FORMING HEAT DISSIPATION PATHWAYS IN A STACKED DEVICE

(71) Applicant: Tokyo Electron Limited, Tokyo (JP)

(72) Inventors: Christopher Michael Netzband, Albany, NY (US); Andrew Tuchman, Albany, NY (US); Ilseok Son, Albany, NY (US)

(21) Appl. No.: 19/042,898

(22) Filed: Jan. 31, 2025

(51) Int. Cl. H01L 21/50; H01L 21/768; H01L 23/00; H01L 23/373; H01L 25/07

(52) U.S. Cl. CPC H10W 95/00; H10W 20/023; H10W 40/258; H10W 40/259; H10W 80/312; H10W 80/327; H10W 90/00

(57) ABSTRACT

A method of forming a stacked wafer includes providing a first processed wafer including a first substrate, a first plurality of metallization layers, and a first dielectric layer including first contacts disposed over a first bonding layer. The method further includes forming a first opening through the first plurality of metallization layers, the first dielectric layer, and the first bonding layer, and providing a second processed wafer including a second substrate, a second plurality of metallization layers, and a second dielectric layer including second contacts disposed over a second bonding layer. And the method further includes bonding the first processed wafer including the first opening with the second processed wafer to form the stacked wafer, and after the bonding, filling the first opening with a thermally conductive material to form a heat dissipation pathway in the stacked wafer.

### TECHNICAL FIELD

The present invention relates generally to semiconductor manufacturing, and, in particular embodiments, to methods for forming heat dissipation pathways in a stacked device.

### BACKGROUND

Electronic devices continue to become more compact while incorporating increasing functionality, leading to greater power density and heat generation within these devices. Heat management presents technical challenges in semiconductor devices, particularly in stacked or three-dimensional configurations where multiple device layers are bonded together. The interface between bonded wafers or devices can act as a thermal barrier, affecting the overall thermal performance of the device stack.

Various approaches exist for managing heat in stacked semiconductor devices. These approaches comprise different arrangements of device layers and positioning of cooling systems within the stack. However, heat dissipation remains an ongoing area of technical development, particularly at bonding interfaces where heat can accumulate.

Thermal management techniques in semiconductor devices often involve trade-offs between device density, performance, and cooling efficiency. The incorporation of thermal management features in stacked devices adds complexity to manufacturing processes and can impact the selection of materials and process integration schemes.

### SUMMARY

In accordance with an embodiment of this disclosure, a method of forming a stacked wafer includes providing a first processed wafer including a first substrate, a first plurality of metallization layers disposed over the first substrate, and a first dielectric layer including first contacts disposed over the first plurality of metallization layers and a first bonding layer. The method further includes forming a first opening through the first plurality of metallization layers, the first dielectric layer, and the first bonding layer, and providing a second processed wafer including a second substrate, a second plurality of metallization layers disposed over the second substrate, and a second dielectric layer including second contacts disposed over the second plurality of metallization layers and a second bonding layer. And the method further includes bonding the first processed wafer including the first opening with the second processed wafer to form the stacked wafer, and after the bonding, filling the first opening with a thermally conductive material to form a heat dissipation pathway in the stacked wafer.

In accordance with another embodiment of this disclosure, a method for forming heat dissipation pathways in a stacked device includes receiving the stacked device in an etch chamber, the stacked device including wafers bonded together, where one of the wafers bonded together includes a substrate, a plurality of metallization layers disposed over the substrate, and a dielectric layer including contacts disposed over the plurality of metallization layers and a bonding layer. The method further includes forming a patterned mask over the wafers bonded together, and etching an opening through the stacked device using the patterned mask as an etch mask, the opening extending into the dielectric layer. And the method further includes filling the opening with thermally conductive material to form a heat dissipation pathway in the stacked device.

And in accordance with yet another embodiment of this disclosure, a method for processing a bonded wafer includes receiving the bonded wafer, the bonded wafer including a plurality of wafers bonded together, where a bottommost wafer of the plurality of wafers includes a substrate, a plurality of metallization layers disposed over the substrate, and a dielectric layer including contacts disposed over the plurality of metallization layers and a bonding layer. The method further includes forming a patterned etch mask over the bonded wafer, the patterned etch mask including a feature pattern, and etching the bonded wafer to form openings according to the feature pattern into the dielectric layer of the bottommost wafer. And the method further includes filling the openings with thermally conductive material to form heat dissipation pathways in the bonded wafer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1J illustrate wafers during various steps of a processing method to form heat dissipation pathways in a stacked device in accordance with an embodiment of this disclosure;

FIG. 2 is a flowchart illustrating the processing method for forming heat dissipation pathways in a stacked device described using FIGS. 1A-1J in accordance with an embodiment of this disclosure;

FIGS. 3A-3E illustrate a stacked device during various steps of a processing method to form heat dissipation pathways in the stacked device in accordance with an embodiment of this disclosure;

FIG. 4 is a flowchart illustrating the processing method for forming heat dissipation pathways in a stacked device described using FIGS. 3A-3E in accordance with an embodiment of this disclosure;

FIG. 5 is a top view of a stacked device illustrating an example distribution of heat dissipation pathways in accordance with an embodiment of this disclosure;

FIG. 6 is a flowchart illustrating a processing method for forming heat dissipation pathways in a stacked device in accordance with an embodiment of this disclosure;

FIG. 7 is a flowchart illustrating a processing method for forming heat dissipation pathways in a stacked device in accordance with another embodiment of this disclosure; and

FIG. 8 is a flowchart illustrating a processing method for forming heat dissipation pathways in a stacked device in accordance with yet another embodiment of this disclosure.

### DETAILED DESCRIPTION OF ILLUSTRATIVE EMBODIMENTS

Heat is produced by components of a chip during device operation. Generally, this heat is dissipated to the outside through the package. However, with 3D integration of chips such as in stacked architectures, the heat dissipation using traditional techniques may be compromised. When multiple dies or chips are stacked to form a stacked device, the bonding interface between the dies forms a thermal barrier trapping heat. As semiconductor devices become more densely packed with increasing functionality, the thermal considerations at these bonding interfaces become more pronounced. Traditional heat management approaches focusing on device orientation and cooling system placement may be constrained by the thermal characteristics of the bonding interface itself. The presence of this thermal barrier at the bonding interface can influence the overall thermal performance of stacked semiconductor devices, potentially affecting device operation and reliability.

Embodiment methods of forming heat dissipation pathways in a stacked device are described in this disclosure. In various embodiments, thermal management in stacked semiconductor devices may be enhanced through the implementation of via structures that create pathways for heat dissipation. These pathways may be formed in each wafer before bonding to form the stacked device, or they may be formed after stacking. In one or more embodiments, the pathways are created by etching holes through the bonding layers (or bonding interfaces) prior to a thinning process, with subsequent filling of these holes after thinning without impacting potential copper bonding interfaces.

In additional embodiments, when implementing multilayer bonding processes, the pathways may be arranged to overlap, forming extended channels throughout the stacked device. These pathways can accommodate various thermal management materials, including microfluidic cooling substances or thermally conductive materials such as metal oxides or metal nitrides. The incorporation of these thermal pathways enables direct heat dissipation routes through the device structure, which may complement existing thermal management approaches while addressing heat accumulation at bonding interfaces during device operation. A benefit of the method of forming heat dissipation pathways in a stacked device of this disclosure is that thermal boundaries created by bonding layers in stacked devices may be addressed such that heat may be conducted more efficiently throughout the various wafers of the stacked device. Further, the thermal conduction between the wafers may be enhanced further through the material used to form the heat dissipation pathways, the shapes of the pathways, and the distribution of the heat dissipation pathways throughout the stacked device.

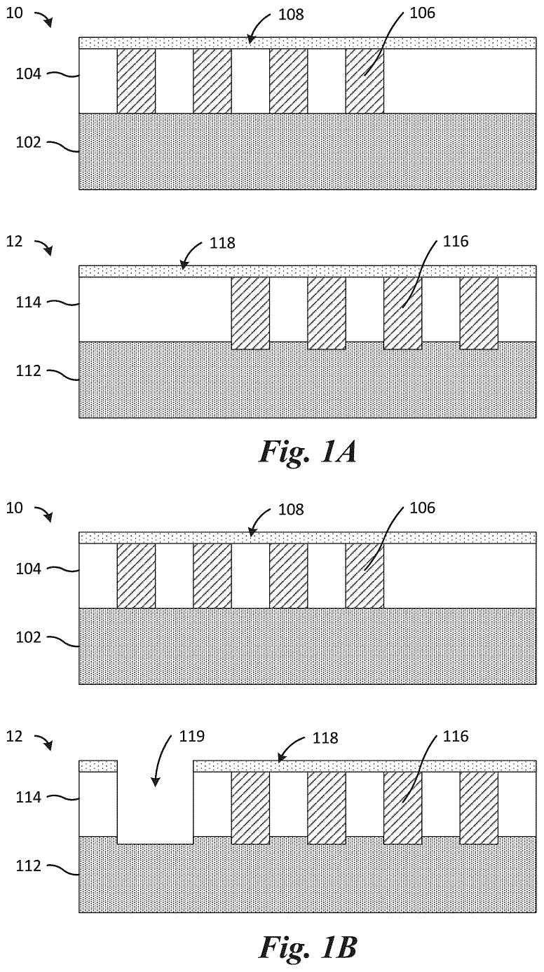

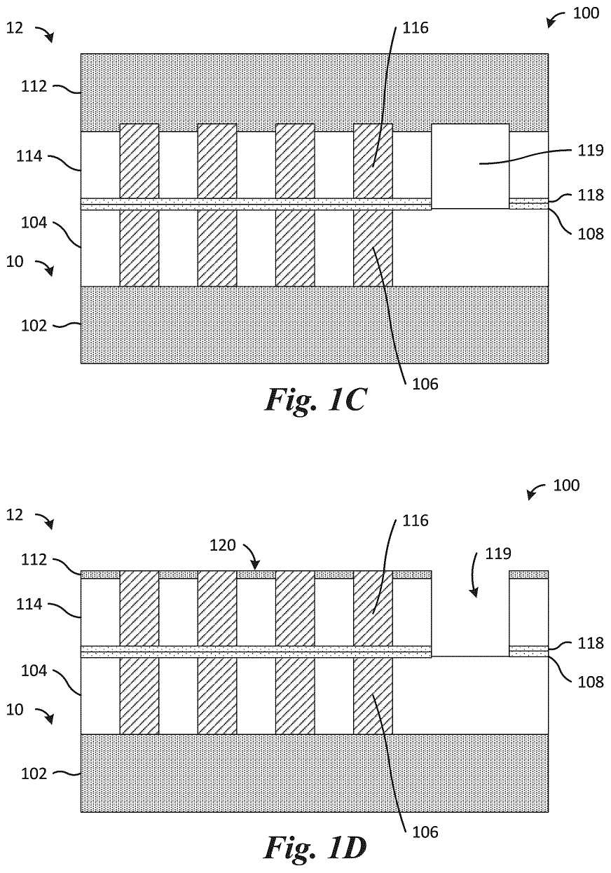

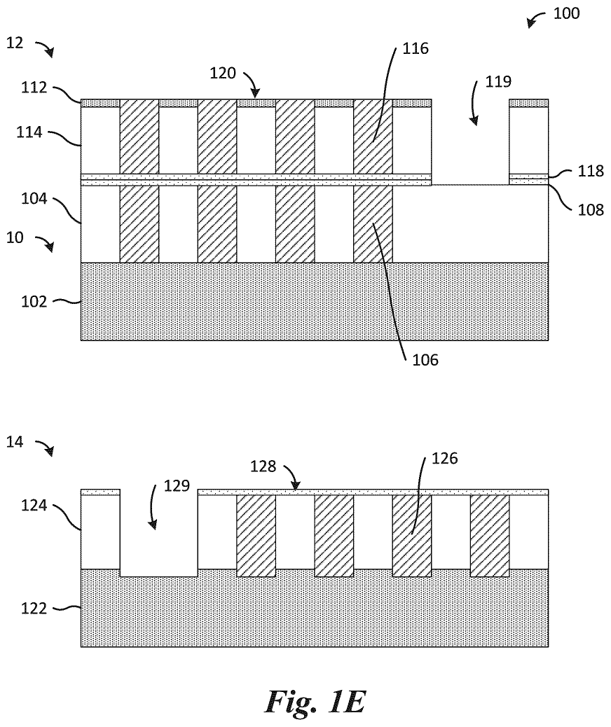

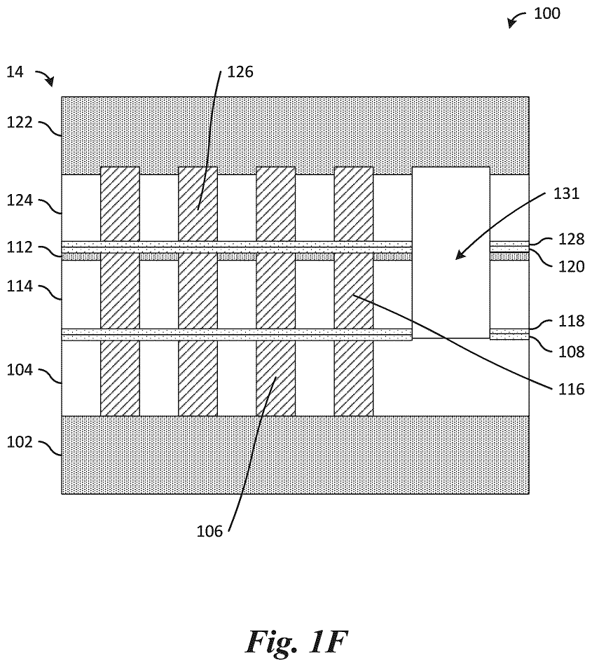

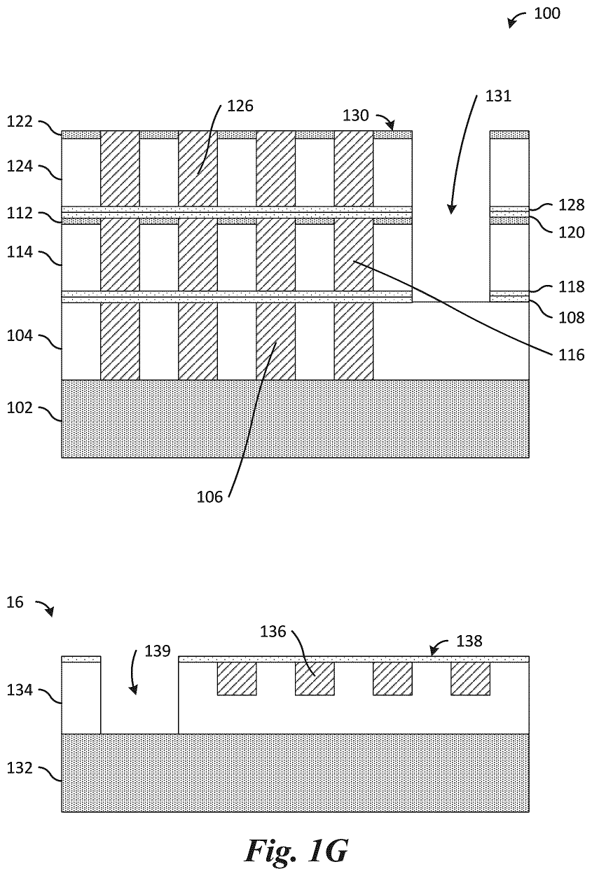

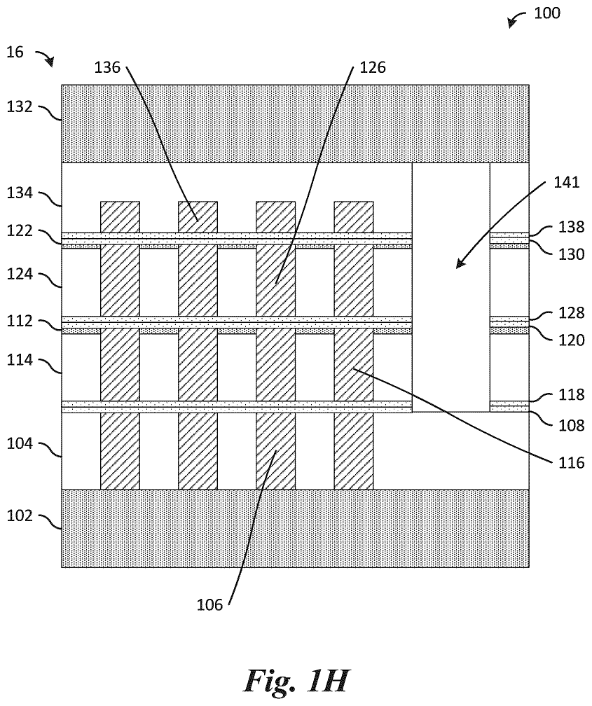

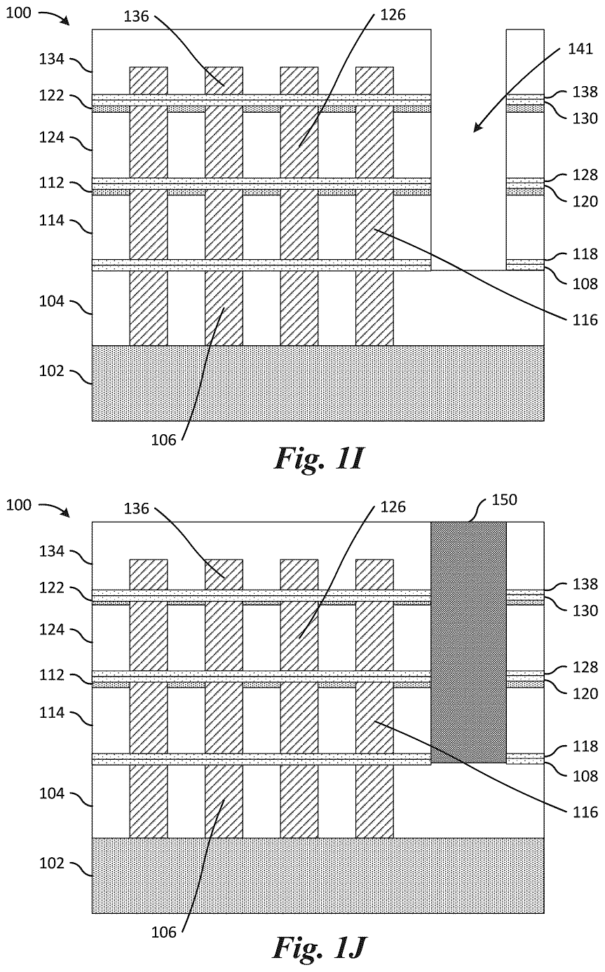

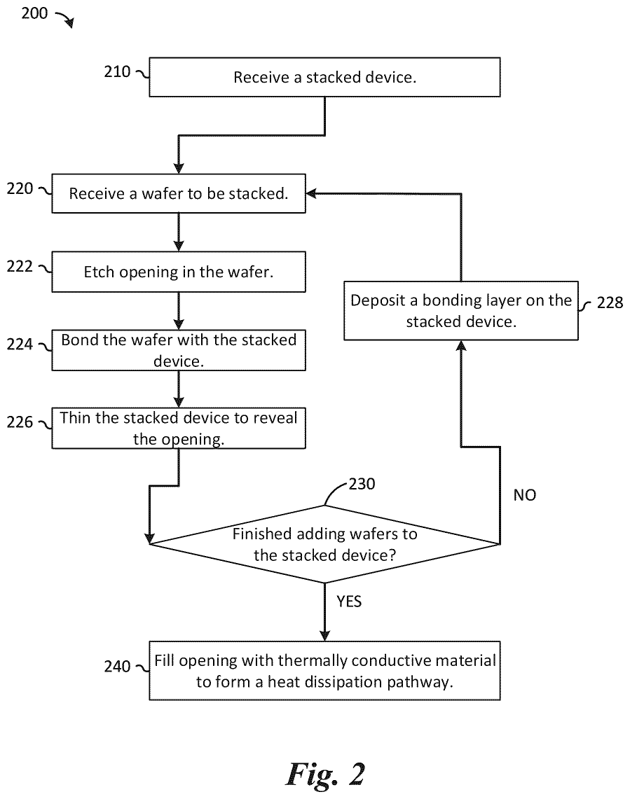

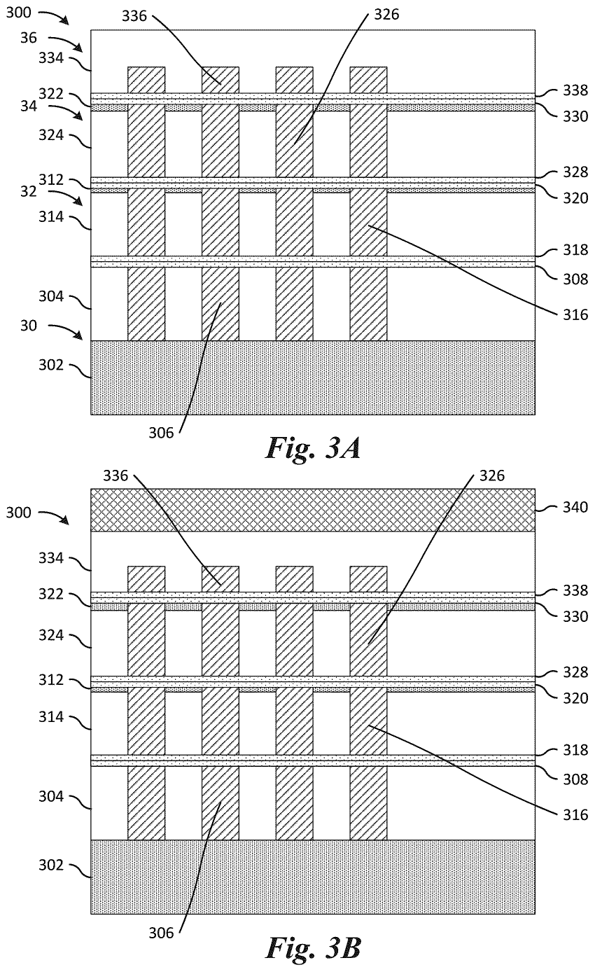

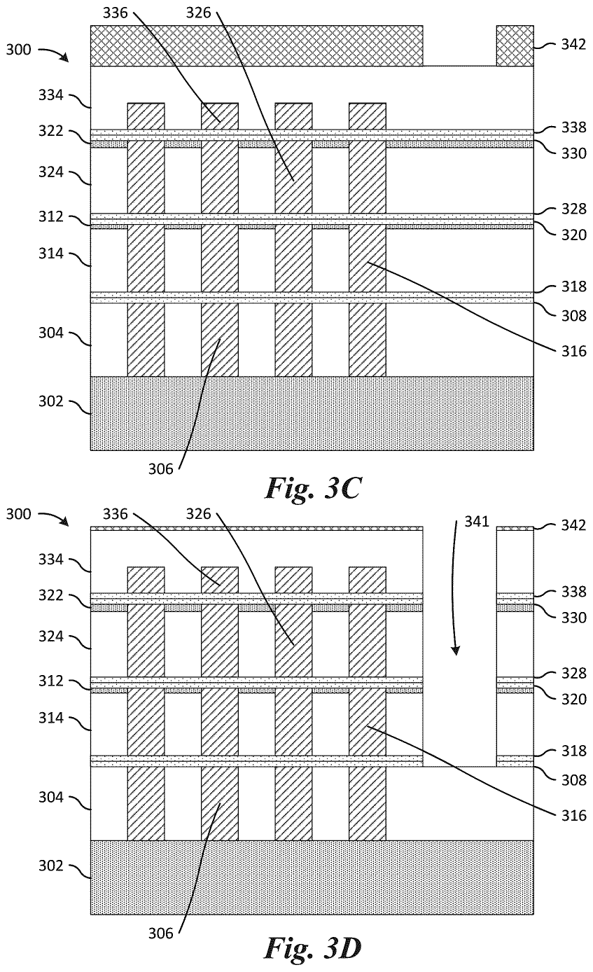

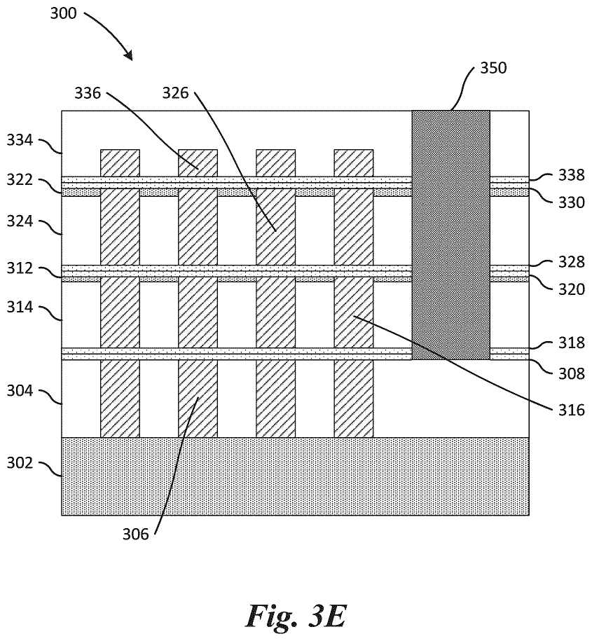

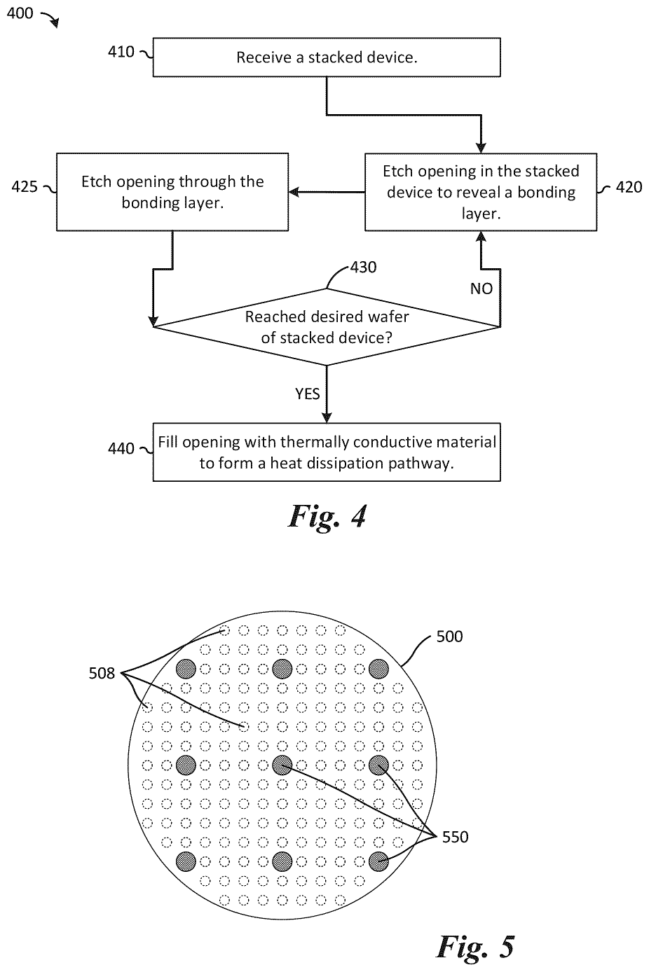

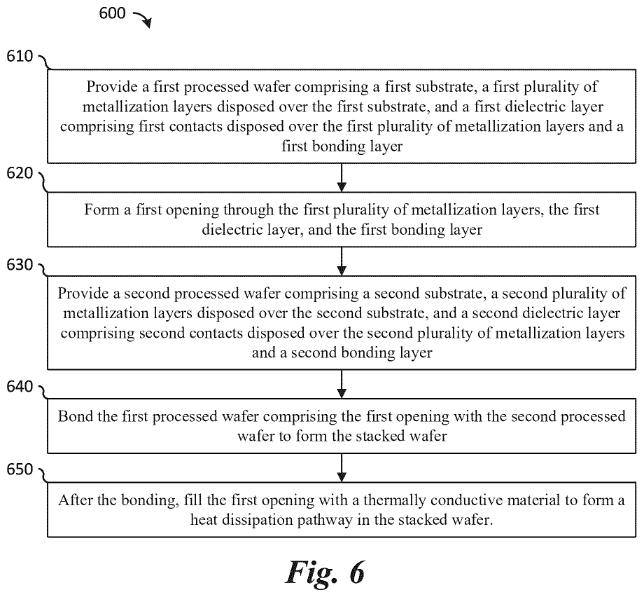

Embodiments provided below describe various methods for processing a substrate, and in particular, to methods of forming heat dissipation pathways in a stacked device. The following description describes the embodiments. FIGS. 1A-1J describe an example processing method for forming a stacked device comprising heat dissipation pathways. FIG. 2 is a flowchart which may be used to describe an embodiment of the method of forming heat dissipation pathways, such as the method illustrated in FIGS. 1A-1J. FIGS. 3A-3E describe another embodiment method of forming heat dissipation pathways in a stacked device. A flowchart which may be used to describe a method of forming heat dissipation pathways in a stacked device, such as illustrated in FIGS. 3A-3E, is illustrated in FIG. 4. FIG. 5 is a top-view of a stacked device used to illustrate an example distribution of heat dissipation pathways which may be formed in accordance with the methods described in this disclosure. And the flowcharts of FIGS. 6-8 illustrate example methods of forming heat dissipation pathways in a stacked device in accordance with embodiments of this disclosure.

FIGS. 1A-1J illustrate wafers during various steps of a processing method to form heat dissipation pathways in a stacked device. In particular, the method illustrated in the various steps of FIGS. 1A-1J intermittently forms openings in wafers prior to bonding them together to form a stacked device. In various embodiments, the method of forming heat dissipation pathways in a stacked device may start by receiving wafers to be stacked, such as described using FIG. 1A.

FIG. 1A illustrates a cross-sectional view of a first wafer 10 and a second wafer 12 during a method of forming a stacked device with heat dissipation pathways. For example, the first wafer 10 and the second wafer 12 may be received as the first step in the method of forming heat dissipation pathways in a stacked device, and the first wafer 10 may be a first processed wafer and the second wafer 12 may be a second processed wafer. In various embodiments, the first wafer 10 and the second wafer 12 may be received as illustrated in FIG. 1A after various processing steps have been performed in accordance with a conventional process flow for forming a stacked device. First wafer 10 comprises a first substrate 102, a first dielectric layer 104 formed over the first substrate 102, and first metal contacts 106 formed in the first dielectric layer 104. The first wafer 10 further comprises a first bonding layer 108 (surface to be bonded) disposed over the first dielectric layer 104 and first metal contacts 106.

In one or more embodiments, the first metal contacts 106 may comprise vias, or metal lines. Further, the first metal contacts 106 may comprise a bonding pad, metal contacts, or another form of metallization feature. In various embodiments, the first metal contacts 106 may comprise metallic materials used to form electrical contacts, metal lines, or vias, such as copper, aluminum, ruthenium, titanium, or tungsten.

In various embodiments, the first dielectric layer 104 may comprise a first metallization layer, or a first plurality of metallization layers comprising metal contacts, metal lines, or vias to form electrical connections between semiconductor device elements (e.g., transistors). In other embodiments, a first plurality of metallization layers (not shown) may be disposed between the first dielectric layer 104 and the first substrate 102. The first plurality of metallization layers of the first dielectric layer 104 may comprise various dielectric layers and a plurality of metallization levels. In further embodiments, the first dielectric layer 104 may comprise multiple layers of dielectrics formed through deposition processes.

In embodiments where the first dielectric layer 104 comprises a first metallization layer or a first plurality of metallization layers, the metallization layers may comprise a metallic material selected from a group including, but not limited to, aluminum, copper, tungsten, ruthenium, or alloys thereof, based on considerations such as electrical conductivity, resistance to electromigration, and compatibility with semiconductor processing temperatures. In one embodiment, the metallization layer is deposited over a dielectric substrate. The dielectric substrate may include materials such as silicon dioxide, silicon nitride, or low-k dielectrics, aimed at reducing parasitic capacitance and enhancing device speed. The metal contacts, metal lines, or vias in each metallization layer may be formed using additive processes such as electroplating or subtractive deposition processes using various deposition techniques such as physical vapor deposition (PVD), chemical vapor deposition (CVD), or sputtering.

To ensure effective adhesion and prevent diffusion of metal into adjacent layers, a barrier layer may be prior to the metal deposition. Suitable barrier materials include tantalum nitride, titanium nitride, or other refractory metals and their compounds.

Following deposition in a subtractive deposition process, the deposited metal is patterned using photolithographic techniques to define conductive pathways. This patterning process may comprise applying a photosensitive resist, exposing it to a desired pattern through a mask, and then developing the resist to etch exposed areas of the metallization. The resulting metallization layers thereby provide reliable electrical interconnections within the stacked device while minimizing resistance and potential short-circuit failures. In advanced embodiments, the metallization layer may comprise multiple stacked layers or incorporate additional functional elements such as vias or interconnects to facilitate three-dimensional integration in complex microelectronic assemblies.

Still referring to FIG. 1A, the first bonding layer 108 may comprise suitable materials for forming a bond between the first wafer 10 and other wafers in various embodiments. For example, in an embodiment where the first wafer 10 may be bonded using an adhesion bonding process, the first bonding layer 108 may comprise an adhesive. As another example, in an embodiment where the first wafer 10 may be bonded using a direct bonding process, the first bonding layer 108 may be a top surface of the first dielectric layer 104 comprising silicon oxide, which may have been treated in a surface activation process. In other embodiments, the first bonding layer 108 may be a topmost, thinly deposited layer of the first dielectric layer 104. Although the first bonding layer 108 is depicted as a thin layer disposed over the first dielectric layer 104, the bonding layer 108 may be of a larger thickness in other embodiments. For example, the thickness of the first bonding layer 108 may be between 5nm and 5 μm.

In various embodiments, the second wafer 12 comprises a second substrate 112, a second dielectric layer 114 formed over the second substrate 112, and second metal contacts 116 formed in the second dielectric layer 114. The second wafer 12 further comprises a second bonding layer 118 disposed over the second dielectric layer 114 and the second metal contacts 116.

The second dielectric layer 114, the second substrate 112, the second metal contacts 116, and the second bonding layer 118 may be as similarly described above for the first dielectric layer 104, the first substrate 102, the first metal contacts 106, and the first bonding layer 108, respectively. For example, the second dielectric layer 114 may comprise a second metallization layer, or a second plurality of metallization layers comprising metal contacts, metal lines, or vias to form electrical connections between semiconductor device elements. Further, a second plurality of metallization layers (not shown) may be disposed between the second dielectric layer 114 and the second substrate 112.

In one or more embodiments, the first substrate 102 and the second substrate 112 may comprise semiconductor materials such as silicon, germanium, compound semiconductors, or combinations thereof. The first dielectric layer 104 and the second dielectric layer 114 may comprise dielectric materials such as silicon oxide, silicon nitride, or low-k dielectric materials. In various embodiments, the first wafer 10 and the second wafer 12 may further comprise a device layer where various electrical devices may have been formed.

First metal contacts 106 and second metal contacts 116 may comprise conductive materials such as copper, aluminum, tungsten, or combinations thereof. In an embodiment, the first bonding layer 108 and the second bonding layer 118 may comprise dielectric materials suitable for wafer bonding, such as silicon oxide or silicon nitride. In other embodiments, the first bonding layer 108 and the second bonding layer 118 may comprise an adhesive. Further, in various embodiments, exposed surfaces of the first bonding layer 108 and the second bonding layer 118 may have been activated through a conventional surface activation process to prepare the first wafer 10 and the second wafer 12 to be bonded together.

FIG. 1B illustrates a cross-sectional view of the structure after performing an etch process to form a first opening 119 in the second wafer 12. In various embodiments, the etch process may comprise a dry etch process, a wet etch process, or combinations thereof. The etch process forms the first opening 119 through second bonding layer 118 while maintaining the structural integrity of second metal contacts 116 and the second dielectric layer 114.

In various embodiments, the first opening 119 may be formed using a conventional photolithography process to pattern a photoresist layer to form a patterned mask and then performing an etching process. The first opening 119 creates a pathway through second bonding layer 118 that may be used to facilitate heat dissipation from the first wafer 10 to the second wafer 12. The formation of the first opening 119 before bonding enables the creation of heat dissipation pathways without compromising the integrity of the bonding interface between the first wafer 10 and the second wafer 12.

In one or more embodiments, the first opening 119 may comprise a width ranging from about 0.5 microns to about 10 microns. In various embodiments, the first opening 119 may be a pillar that can be filled with thermally conductive material in subsequent steps to form a conductive pillar. The depth of first opening 119 extends through the entire thickness of the second bonding layer 118, through the entire thickness of the second dielectric layer 114, and partially extends into the second substrate 112. This configuration of first opening 119 creates a designated pathway for subsequent heat dissipation features while maintaining sufficient bonding surface area between the first bonding layer 108 of the first wafer 10 and the second bonding layer 118 of the second wafer 12.

In various embodiments, the etch process may be used to form a plurality of openings, where the first opening 119 may be one opening of the plurality of openings spanning the second wafer 12. In those embodiments, the distribution of the plurality of openings across the second wafer 12 may be chosen to optimize heat dissipation capabilities of the device being fabricated. For example, the distribution of the plurality of openings across the second wafer 12 may prioritize heat dissipation from regions of the device that may produce a large amount of thermal energy during device operation. Further, the distribution of the plurality of openings may be determined to reduce or prevent parasitic effects of heat dissipation pathways with the various metal contacts. In various embodiments, a portion of the first bonding layer 108 that would overlap with the first opening 119 of the second wafer 12 may also be removed through a similar photolithography and etching process. As a result, when the first wafer 10 and the second wafer 12 are bonded, the first opening 119 would be open to the first dielectric layer 104 of the first wafer 10.

FIG. 1C illustrates a cross-sectional view of the structure after bonding the first wafer 10 and the second wafer 12 to form a stacked device 100 or a stacked wafer. In various embodiments, the bonding process may comprise a direct bonding process, where the first bonding layer 108 and the second bonding layer 118 are brought into direct contact under controlled temperature and pressure conditions. During the bonding process, the first opening 119 remains open and unobstructed. In various embodiments, the first bonding layer 108 and the second bonding layer 118 form a bonding interface which may prevent heat dissipation between wafers of the stacked wafer. In one or more embodiments, the first wafer 10 and the second wafer 12 are bonded through the first dielectric layer 104 and the second dielectric layer 114 to form a bonding interface between the first wafer 10 and the second wafer 12 without using the first bonding layer 108 and the second bonding layer 118. The method of forming heat dissipation pathways in a stacked device of this disclosure may also be used for other bonding processes for forming a stacked device, such as through direct bonding, fusion bonding, hybrid bonding, thermocompressive bonding, or adhesion bonding.

In one or more embodiments, the bonding process may be performed at temperatures ranging from about 25° C. to about 400° C. The applied pressure during bonding may range from about 0.5 MPa to about 5 MPa. These bonding conditions enable formation of strong chemical bonds between the first bonding layer 108 and the second bonding layer 118 while preserving the structural integrity of the first opening 119. As illustrated in FIG. 1C, the bonding process bonds the second wafer 12 with the first wafer 10 such that the first opening 119 forms a pathway through to the first dielectric layer 104 of the first wafer 10.

The stacked device 100 is a bonded structure that establishes electrical connections between first metal contacts 106 and second metal contacts 116 while simultaneously creating a foundation for heat dissipation pathways through the first opening 119. This configuration enables both electrical connectivity and the first opening 119 may be used to form thermal management features in the resulting stacked device 100 in subsequent processing steps.

After bonding the second wafer 12 with the first wafer 10, the second substrate 112 is thinned such as described using FIG. 1D.

FIG. 1D illustrates a cross-sectional view of the stacked device 100 after thinning the second substrate 112 of the second wafer 12 to expose the first opening 119 and the second metal contacts 116. In various embodiments, the second substrate 112 may be thinned down without removing the active device regions, e.g., using a timed etching/planarization process. After bonding and thinning, a third bonding layer 120 may be deposited over the thinned second substrate 112 and the exposed second metal contacts 116. In an embodiment, the third bonding layer 120 may comprise dielectric materials similar to those used for first bonding layer 108 and the second bonding layer 118. In other embodiments, the third bonding layer 120 may be as previously described for the first bonding layer 108 or the second bonding layer 118. The formation of the third bonding layer 120 prepares the surface for subsequent bonding operations while maintaining access to the first opening 119. In various embodiments, the third bonding layer 120 may be treated in an activation process to prepare the third bonding layer 120 for bonding additional wafers with the stacked device 100. The activation process may be a wet etching process or a plasma surface activation process in various embodiments.

FIG. 1E illustrates a cross-sectional view of the stacked device 100 and a third wafer 14 that has been similarly prepared as the second wafer 12 for bonding with the stacked device 100. The third wafer 14 comprises a third substrate 122, a third dielectric layer 124 formed over the third substrate 122, and third metal contacts 126 formed in the third dielectric layer 124. The third wafer 14 further comprises a fourth bonding layer 128 disposed over the third dielectric layer 124 and third metal contacts 126, and a second opening 129 through the fourth bonding layer 128, the third dielectric layer 124, and partially extending into the third substrate 122. In various embodiments, the fourth bonding layer 128 may have been treated using a surface activation process to prepare the third wafer 14 to be bonded with the stacked device 100.

In various embodiments, the third substrate 122 may comprise semiconductor materials similar to those used in the first substrate 102 and the second substrate 112. The third dielectric layer 124 may comprise dielectric materials similar to those used in the first dielectric layer 104 and the second dielectric layer 114, or the third dielectric layer 124 may be as previously described for the first dielectric layer 104 or the second dielectric layer 114. The third metal contacts 126 may comprise conductive materials similar to those used in the first metal contacts 106 and the second metal contacts 116, and may be similar features as described for the first metal contacts 106 or the second metal contacts 116.

A second opening 129 is formed through fourth bonding layer 128 prior to bonding with the underlying structure. In one or more embodiments, the second opening 129 is formed using photolithography and etching processes similar to those used to form the first opening 119. In subsequent steps, the second opening 129 may be positioned to align with the first opening 119, enabling formation of a coupled opening after the bonding process.

In an embodiment, fourth bonding layer 128 may comprise dielectric materials suitable for wafer bonding, similar to those used in previous bonding layers. The alignment of second opening 129 with first opening 119 creates a continuous pathway through multiple bonding interfaces, enhancing the heat dissipation capabilities of stacked device 100.

FIG. 1F illustrates a cross-sectional view of the structure after bonding the third wafer 14 to the underlying structure to add the third wafer 14 to the stacked device 100. The bonding process joins the fourth bonding layer 128 with the third bonding layer 120, creating a first coupled opening 131 from the aligned first opening 119 and second opening 129. And by using the method of forming a stacked device described using FIGS. 1A-1J, the first coupled opening 131 extends through the topmost wafer (the third wafer 14) down to the bottommost wafer (the first wafer 10) through the various bonding layers.

In various embodiments, the bonding process for third wafer 14 may comprise temperature and pressure conditions similar to those used for bonding first wafer 10 and second wafer 12. The alignment of first opening 119 and second opening 129 during the bonding process creates first coupled opening 131, which extends through multiple bonding interfaces of stacked device 100.

The bonded structure establishes electrical connections between third metal contacts 126 and the underlying metal contacts while maintaining first coupled opening 131 for thermal management. In an embodiment, the width and depth of first coupled opening 131 remain consistent through the multiple bonding layers, facilitating uniform heat dissipation throughout the stacked structure.

After bonding the third wafer 14 with the stacked device 100, the method may proceed to thin the third substrate 122 through similar methods as described for thinning the second substrate 112 in various embodiments. Other embodiments may use any suitable thinning method to thin the third substrate 122 and reveal the first coupled opening 131.

FIG. 1G illustrates a cross-sectional view of a fourth wafer 16 prepared to be bonded through suitable processes with the stacked device 100. FIG. 1G also illustrates the stacked device 100 after thinning the third substrate 122 through a suitable thinning method, and after depositing a fifth bonding layer 130 over the thinned third substrate 122. The fourth wafer 16 comprises a fourth substrate 132, a fourth dielectric layer 134 formed over the fourth substrate 132, and fourth metal contacts 136 formed in the fourth dielectric layer 134. A sixth bonding layer 138 is formed over the fourth dielectric layer 134 and the fourth metal contacts 136.

In various embodiments, fourth substrate 132 may comprise semiconductor materials similar to those used in the previous substrates. Fourth dielectric layer 134 may comprise dielectric materials similar to those used in the previous dielectric layers. The fourth dielectric layer 134 may also be as previously described for the previous dielectric layers. Fourth metal contacts 136 may comprise conductive materials similar to those used in the previous metal contacts, and the fourth metal contacts 136 may be as previously described for the previous metal contacts.

A third opening 139 is formed through the sixth bonding layer 138 prior to bonding. In one or more embodiments, third opening 139 is formed using photolithography and etching processes similar to those used to form previous openings. Third opening 139 is positioned to align with first coupled opening 131, enabling formation of second coupled opening 141 after the bonding process.

In an embodiment, sixth bonding layer 138 may comprise dielectric materials suitable for wafer bonding, similar to those used in previous bonding layers. In one or more embodiments, fifth bonding layer 130 may comprise dielectric materials similar to those used in previous bonding layers. The formation of fifth bonding layer 130 prepares the surface for subsequent bonding while maintaining access to first coupled opening 131. This layered structure enables the creation of extended heat dissipation pathways through multiple device layers.

FIG. 1H illustrates a cross-sectional view of the stacked device 100 after bonding the fourth wafer 16 to the underlying structure. The bonding process joins sixth bonding layer 138 with fifth bonding layer 130, aligning third opening 139 with first coupled opening 131 to form a second coupled opening 141. In various embodiments, the bonding process for fourth wafer 16 may comprise temperature and pressure conditions similar to those used in previous bonding steps. The alignment of third opening 139 with first coupled opening 131 extends the continuous pathway through additional bonding interfaces, further enhancing the heat dissipation capabilities of stacked device 100. After bonding the fourth wafer 16 with the stacked device 100, the fourth substrate 132 may be thinned to reveal the second coupled opening 141.

FIG. 1I shows a cross-sectional view of the structure after completion of the bonding processes and after thinning the fourth substrate 132 to reveal the second opening 141. Second coupled opening 141 extends through multiple bonding interfaces, creating a continuous pathway from the uppermost bonding layer to the lowermost bonding layer of stacked device 100. In one or more embodiments, the width of second coupled opening 141 may remain substantially uniform throughout its depth. In various embodiments, the second coupled opening 141 is a pillar which may be filled with thermally conductive materials to form heat dissipation pathways in accordance with embodiments of this disclosure.

FIG. 1J illustrates the stacked device 100 after the formation of a heat dissipation pathway 150. In various embodiments, the heat dissipation pathway 150 may be formed by filling second coupled opening 141 with thermally conductive materials. In various embodiments, the filling of the second coupled opening 141 may be filled through any suitable method for the specified thermally conductive material.

In one or more embodiments, the thermally conductive materials may comprise a solid layer and may comprise metal oxides, metal nitrides, pure metals, or combinations thereof, such as copper, aluminum oxide, aluminum nitride, hafnium oxide, boron nitride, silicon nitride, or polysilicon.

In one or more embodiments, the thermally conductive materials may comprise microfluidics. For example, in an embodiment using microfluidics as the thermally conductive material, the microfluidics may be filled into the second coupled opening 141 to form the heat dissipation pathway 150. Microfluidics refers to the behavior, precise control, and manipulation of fluids that are geometrically constrained to a small scale, typically sub-millimeter dimensions. In one or more embodiments, the microfluidic materials may include liquids that can fill the small channels created in the stacked device to dissipate heat. Examples of microfluidic materials suitable for heat dissipation may include, but are not limited to, water, ethylene glycol, propylene glycol, or specialized heat transfer fluids. Glycols, including ethylene glycol and propylene glycol, are known for their thermal properties and stability over a wide temperature range. The thermal conductivity of ethylene glycol, for example, is approximately 0.25 W/(m·K) at room temperature, which is higher than that of many other non-metallic liquids. This property allows glycols to effectively transfer heat from warmer areas of the stacked device to cooler areas, enhancing overall thermal management. The use of glycol in heat dissipation pathways provides a non-corrosive, electrically insulating option for improving heat distribution within the stacked device structure. In some embodiments, the microfluidics may also be able to internally circulate within the heat dissipation pathways of the stacked device for improved heat transfer.

FIG. 1J shows the completed stacked device 100 comprising the heat dissipation pathway 150 formed through the multiple device layers. In an embodiment, heat dissipation pathway 150 provides a direct thermal pathway through the bonding interfaces of stacked device 100. This configuration enables efficient heat transfer from various layers of stacked device 100, reducing thermal resistance between bonded interfaces and improving overall device performance. In various embodiments, the heat dissipation pathway 150 is isolated from electrical connections formed throughout the stacked device 100, such as through an isolation layer deposited in the openings prior to filling the openings with the thermally conductive material. In other embodiments, the heat dissipation pathway 150 may be grounded to prevent parasitic currents as a result of proximity of the heat dissipation pathway 150 with electrical connections of the stacked device 100.

The completed structure provides both electrical connectivity through the metal contacts and thermal management through heat dissipation pathway 150. In various embodiments, multiple heat dissipation pathways may be formed throughout stacked device 100 to optimize thermal management based on specific device operational characteristics and heat generation patterns. An example distribution of heat dissipation pathways is described further using FIG. 5.

Additionally, in other embodiments, the bonding layers of the stacked device 100 may be a bonding interface formed through the bonding of the dielectric layers of the wafers rather than distinct bonding layers. As an example, the dielectric layers or metallization layers may be bonded directly, which forms bonding interfaces between the stacked wafers. In various embodiments, the distribution of electrical devices and elements of the device being fabricated may be positioned to enable the formation of the heat dissipation pathway 150. In other words, the stacked device 100 may be designed to leave particular areas open that may benefit from a heat dissipation pathway such that the heat dissipation pathway 150 may be formed to improve thermal mitigation of the stacked device 100 during operation. In various embodiments, after forming the stacked device 100 in FIG. 1J, further processing steps may be performed to finish the device, such as by singulating the stacked device 100.

FIG. 2 is a flowchart illustrating a method 200 for forming heat dissipation pathways in a stacked device, such as the processing method described using FIGS. 1A-1J to form the stacked device 100. The method 200 may start with step 210 by receiving a stacked device. In various embodiments, the stacked device may comprise various wafers bonded together. In other embodiments, the stacked device may be a single wafer comprising a bonding layer disposed over underlying layers, such as alternating dielectric layers or a single dielectric layer comprising metal contacts to form electrical connections with other wafers. In further embodiments, a bottom wafer of the stacked device may comprise a device layer with various circuit components, such as transistors, resistors, capacitors, or others. As an example, in an embodiment, the stacked device may comprise a single wafer, such as the first wafer 10 in FIG. 1A. Additionally, in various embodiments, step 210 of the method 200 may be illustrated by FIG. 1A.

The method 200 may then proceed to step 220. In step 220, the method 200 receives a wafer to be stacked. For example, the wafer to be stacked on the stacked device may comprise a bonding layer disposed over underlying layers. In an embodiment, the wafer received in step 220 may be the second wafer 12 in FIG. 1A. Further, the wafer received in step 220 of the method 200 may be illustrated by FIG. 1A.

After receiving the wafer in step 220, the method 200 may proceed to step 222. In step 222, the method 200 etches an opening in the wafer. The etching performed in step 222 may be performed by any suitable etch process for forming the desired opening in the wafer. For example, a plasma process may be used to etch the openings in the wafer, such as by using a capacitively-coupled plasma (CCP) or an inductively coupled plasms (ICP). The etch process of step 222 etches the opening through the bonding layer and underlying layers of the wafer. In various embodiments, the opening may be a suitable feature for forming a heat dissipation pathway, such as a pillar.

Once the opening is formed in the wafer in step 222, the method 200 proceeds to step 224. In step 224, the method 200 bonds the wafer with the stacked device through a suitable bonding method such as direct bonding, fusion bonding, hybrid bonding, thermocompressive bonding, or adhesion bonding. The bonding layer of the wafer is bonded with the bonding layer of the stacked device. In various embodiments, step 224 may be represented by the bonding of the first wafer 10 with the second wafer 12 in FIG. 1C.

After bonding the wafer comprising the opening with the stacked device in step 224, the method 200 may proceed to step 226. In step 226, the method 200 thins the stacked device (the backside of the wafer comprising the opening) to reveal the opening. In various embodiment, any suitable thinning process may be used, such as chemical mechanical planarization (CMP) processes.

After thinning the stacked device to reveal the opening of the newly bonded wafer in step 226, the method 200 proceeds to step 230. In step 230, the method 200 determines whether the amount of wafers to be stacked according to the process recipe have been bonded to form the stacked device. If the desired number of wafers have not been stacked to form the stacked device with openings aligned, the method 200 proceeds to step 228. In step 228, the method 200 deposits a bonding layer on the stacked device through a suitable deposition process, such as ALD or CVD. And after step 228, the method 200 proceeds back to step 220 to receive another wafer to be etched and bonded with the stacked device until step 230 determines the desired number of wafers have been bonded to form the stacked device with an opening extending through the stacked device.

If the desired number of wafers have been stacked to form the stacked device with the openings aligned, the method 200 proceeds to step 240. In step 240, the method 200 fills the opening with thermally conductive material to form a heat dissipation pathway in the stacked device. Any suitable thermally conductive material may be used to fill the opening in the stacked device, such as a metal oxide, or a microfluidic. Additionally, any suitable deposition method may be used to fill the openings in the stacked device and form the heat dissipation pathways. In various embodiments, step 240 may be represented by FIG. 1J.

FIGS. 3A-3E illustrate a stacked device 300 during various steps of another embodiment processing method to form heat dissipation pathways. The difference between the processing method described using FIGS. 1A-1J and the processing method described using FIGS. 3A-3E is that the processing method of FIGS. 3A-3E perform an etch step to form the heat dissipation pathways after stacking the various wafers of the stacked device 300.

FIG. 3A illustrates a cross-sectional view of a stacked device 300 comprising multiple wafers at a stage of processing to form openings which may be used as heat dissipation pathways. In the embodiment illustrated in FIGS. 3A-3E, the stacked device 300 comprises a first wafer 30, a second wafer 32, a third wafer 34, and a fourth wafer 36 bonded together in a vertical stack arrangement. Other embodiments may comprise fewer or more wafers bonded together to form the stacked device 300. Additionally, this method may be performed on stacked devices comprising fewer or more wafers in other embodiments.

The first wafer 30 comprises a first dielectric layer 304 disposed over a first substrate 302. As illustrated in FIG. 3A, the first dielectric layer 304 comprises first metal contacts 306, which may have been formed through a suitable method. The first wafer 30 further comprises a first bonding layer 308 disposed over the first dielectric layer 304 and first metal contacts 306. In various embodiments, the first metal contacts 306 provide electrical connections through the first dielectric layer 304 and may form interconnects with underlying circuitry of the first wafer 30.

The second wafer 32 comprises a second dielectric layer 314 disposed over a second substrate 312. In various embodiments, the second dielectric layer 314 comprises second metal contacts 316 which may have been formed through a suitable conventional method. The second wafer 32 further comprises a second bonding layer 318 disposed over the second dielectric layer 314 and second metal contacts 316. As illustrated in FIG. 3A, the second bonding layer 318 may be bonded with the first bonding layer 308 to form a bonding interface between the first wafer 30 and the second wafer 32.

A third dielectric layer 324 is disposed on the third wafer 34 over a third substrate 322. Third metal contacts 326 may be formed within the third dielectric layer 324, and a third bonding layer 320 is disposed between the second substrate 312 and the third dielectric layer 324 and third metal contacts 326. A fifth bonding layer 330 is disposed on an opposite side of the third substrate 322.

The fourth wafer 36 comprises a fourth dielectric layer 334 which may comprise fourth metal contacts 336 formed within the fourth dielectric layer 334. In various embodiments, the fourth wafer 36 may be bonded to the third wafer 34 through a sixth bonding layer 338 disposed over the fourth dielectric layer 334 and fourth metal contacts 336, the sixth bonding layer 338 bonded to the fifth bonding layer 330. In an embodiment, a mask 340 is formed over the sixth bonding layer 338 to define locations for forming heat dissipation pathways through the stacked device 300.

In various embodiments, the bonding layers form bonding interfaces which enable wafer-to-wafer bonding while diminishing thermal conduction between the wafers of the stacked device 300. The method of forming heat dissipation pathways of this disclosure may be used to form heat dissipation pathways in the stacked device 300 to enable efficient thermal conduction between the various wafers through the bonding layers (bonding interfaces). Further, the vertical arrangement of the wafers with intervening bonding layers enables efficient use of space and the implementation of heat dissipation pathways may further improve thermal management capabilities when the stacked device 300 is operated.

After receiving the stacked device 300 in FIG. 3A, the method of forming heat dissipation pathways may proceed to perform various steps to form heat dissipation pathways.

FIG. 3B illustrates the stacked device 300 after forming a mask 340 over the fourth dielectric layer 334. In various embodiments, the mask 340 may comprise a photoresist material, a hard mask material, or combinations thereof. The photoresist material may comprise positive photoresist, negative photoresist, or metal oxide resist. The hard mask material may comprise silicon oxide, silicon nitride, silicon oxynitride, or metal-containing materials.

In an embodiment, the mask 340 is deposited using spin coating when the mask comprises photoresist materials. When the mask 340 comprises hard mask materials, the deposition may be performed using chemical vapor deposition (CVD), plasma enhanced chemical vapor deposition (PECVD), atomic layer deposition (ALD), physical vapor deposition (PVD), or spin-on deposition techniques.

The thickness of the mask 340 may vary based on subsequent etching processes. In one or more embodiments, the mask thickness may range from about 100 nm to about 2000 nm for photoresist materials, and from about 10 nm to about 500 nm for hard mask materials. The mask 340 serves as a protective layer during subsequent patterning processes to form heat dissipation pathways through the stacked device 300.

In various embodiments, when the mask 340 comprises photoresist material, the deposition process may further comprise a pre-baking step at temperatures ranging from about 70° C. to about 150° C. to remove solvents from the photoresist. The pre-baking step may be performed for a duration ranging from about 30 seconds to about 180 seconds.

FIG. 3C illustrates the stacked device 300 after patterning the mask 340 to form a patterned mask 342. In various embodiments, when the mask 340 comprises photoresist material, the patterning process may comprise exposure to radiation followed by development. The radiation may comprise ultraviolet light, deep ultraviolet light, extreme ultraviolet light, e-beam, or x-ray radiation.

In one or more embodiments, the patterning process may comprise a post-exposure baking step at temperatures ranging from about 90° C. to about 150° C. The post-exposure baking step may be performed for a duration ranging from about 30 seconds to about 180 seconds. Development of the exposed photoresist may be performed using wet development or dry development techniques.

When the mask 340 comprises hard mask material, the patterning process may comprise forming a photoresist layer over the hard mask, patterning the photoresist layer, and transferring the pattern to the hard mask using an etching process. The etching process may comprise wet etching, dry etching, or combinations thereof.

In various embodiments, the patterned mask 342 defines locations for forming openings through multiple layers of the stacked device 300. For example, the patterned mask 342 comprises a feature pattern for forming pillars which may be subsequently filled with thermally conductive material. The pattern transfer may be achieved through subsequent etching processes using the patterned mask 342 as an etch mask.

FIG. 3D illustrates the stacked device 300 after performing an etch process to form opening 341 through multiple layers using the patterned mask 342. In various embodiments, the opening 341 may be a pillar or some other suitable feature to be used as a heat dissipation pathway. In various embodiments, the etch process may comprise dry etching, wet etching, or combinations thereof to transfer the feature pattern through the dielectric layers and bonding layers of the stacked device 300.

The dry etching process may comprise reactive ion etching (RIE), inductively coupled plasma (ICP) etching, or capacitively coupled plasma etching. In one or more embodiments, for etching through dielectric layers 304, 314, 324, and 334, the etch chemistry may comprise fluorocarbon-based gases such as CF₄, C₄F₈, CHF₃, CH₂F₂, C₂F₆, C₂F₄H₂, SF₆, NF₃, or combinations thereof, with an optional addition of Ar, N₂, Cl₂ or O₂. The etch process through the dielectric layers may be performed at pressures ranging from about 1 mTorr to about 1000 mTorr and plasma power ranging from about 100W to about 3000W.

For etching through bonding layers 308, 318, 320, 328, 330, and 338, the etch chemistry may comprise chlorine-based gases such as Cl₂, BCl₃, HCl, or combinations thereof, with optional addition of Ar, N₂, or He. The etch process through the bonding layers may be performed at pressures ranging from about 1 mTorr to about 500 mTorr and plasma power ranging from about 200 W to about 2000 W.

In an embodiment, a cyclic etch process alternates between fluorocarbon-based chemistry and chlorine-based chemistry as the etch progresses through alternating dielectric and bonding layers. The process parameters may be adjusted during each cycle to optimize etch selectivity and profile control. A first cycle may employ fluorocarbon-based chemistry to etch through a dielectric layer, followed by a second cycle using chlorine-based chemistry to etch through a bonding layer. This sequence may repeat until the opening 341 extends through the desired number of layers in the stacked device 300.

In various embodiments, endpoint detection techniques may be employed to determine layer transitions and adjust etch parameters accordingly. These techniques may comprise optical emission spectroscopy, interferometry, or mass spectrometry to monitor etch progress through different material layers.

FIG. 3E illustrates the stacked device 300 after removing the patterned mask 342 and forming a heat dissipation pathway 350 within the opening 341. In various embodiments, removal of the patterned mask 342 may comprise wet stripping, dry stripping, or combinations thereof. For photoresist masks, the stripping process may use oxygen-based plasma or wet chemical solutions. For hard masks, the stripping process may use selective wet etchants or selective dry etch chemistries.

The heat dissipation pathway 350 may comprise thermally conductive materials deposited at temperatures below 400° C. In one or more embodiments, the thermally conductive material may comprise metals such as copper, aluminum, tungsten, or alloys thereof. The thermally conductive material may alternatively comprise metal nitrides such as titanium nitride, tantalum nitride, or tungsten nitride, or metal oxides such as aluminum oxide or titanium oxide.

The deposition process for forming the heat dissipation pathway 350 may comprise chemical vapor deposition (CVD), atomic layer deposition (ALD), physical vapor deposition (PVD), electroplating, or electroless plating. In an embodiment using CVD, the process may employ metal-organic precursors with reducing agents at temperatures ranging from about 150° C. to about 350° C. For ALD processes, the deposition may use sequential exposure to precursor gases with purge steps at temperatures ranging from about 100° C. to about 300° C. Thermally conductive materials such as aluminum oxide may be deposited using CVD or ALD in different embodiments.

In various embodiments, the heat dissipation pathway 350 may form a pillar structure extending vertically through multiple layers of the stacked device 300. The pillar structure may comprise a circular, rectangular, or polygonal cross-section with dimensions ranging from about 50 nm to about 1000 nm. Multiple heat dissipation pathways may be arranged in arrays or patterns to optimize heat distribution throughout the stacked device 300.

The heat dissipation pathway 350 may be distributed to avoid parasitic effects with the metal contacts 306, 316, 326, and 336, and to enhance thermal conductivity between different layers of the stacked device 300. In one or more embodiments, the interface between the heat dissipation pathway 350 and surrounding materials may comprise adhesion layers or barrier layers to prevent material diffusion while maintaining thermal conductivity. The heat dissipation pathway 350 may be electrically isolated using isolation layers deposited before filling with thermally conductive material. In other embodiments, the heat dissipation pathway 350 may be grounded to mitigate parasitic currents in the thermally conductive material during device operation.

In various embodiments, the heat dissipation pathways 350 penetrate through the bonding layers 308, 318, 320, 328, 330, and 338 to create direct thermal connections between the first wafer 30, second wafer 32, third wafer 34, and fourth wafer 36. The thermal conductivity through these pathways may be substantially higher than the thermal conductivity through the bonding layers alone. When the stacked device 300 generates heat during operation, the heat dissipation pathways 350 provide efficient thermal transport routes from heat-generating regions to heat-dissipating regions of the stacked device 300. The vertical arrangement of the heat dissipation pathways 350 through multiple wafer layers enables three-dimensional heat spreading throughout the stacked device 300.

In one or more embodiments, the various dielectric layers of the stacked device 300 may be as previously described for the stacked device 100. For example, the dielectric layers may comprise metallization layers disposed between a corresponding substrate and the dielectric layer. In other embodiments, pluralities of metallization layers may be formed between the dielectric layers and the substrates. Additionally, the metal contacts may be as previously described for the metal contacts of the stacked device 100. As another example, the metal contacts may comprise contacts, vias, or metal lines comprising conductive materials such as copper, aluminum, ruthenium, titanium, or tungsten in various embodiments.

In other embodiments, the bonding layers may be bonding interfaces formed between dielectric layers of the stacked device 300 rather than distinct layers deposited over the corresponding wafers. And as previously described for the stacked device 100, the stacked device 300 may also be designed to arrange the electrical components and features of the stacked device 300 such that the heat dissipation pathway 350 may be formed without damaging elements of the stacked device 300.

FIG. 4 is a flowchart illustrating a method 400 for forming heat dissipation pathways in a stacked device, such as the processing method for forming the heat dissipation pathways 350 in stacked device 300 described using FIGS. 3A-3E. In various embodiments, the method 400 may start in step 410. In step 410, the method 400 receives a stacked device. For example, the stacked device may comprise multiple wafers bonded together with bonding layers separating each wafer of the stacked device. In various embodiments, the stacked device may be the stacked device 300 in FIG. 3A, and step 410 may be the process described and illustrated using FIG. 3A.

After receiving the stacked device in step 410, the method 400 proceeds to step 420. In step 420, the method 400 etches an opening in the stacked device to reveal a bonding layer. And after etching the opening through the bonding layer in step 420, the method 400 proceeds to step 425. In step 425, the method 400 etches the opening through the bonding layer revealed in step 420.

After etching through the bonding layer in step 425, the method 400 proceeds to step 430. And in step 430, the method 400 checks whether the desired wafer of the stacked device has been reached by the opening. If the desired wafer of the stacked device has not been reached by the opening, the method 400 proceeds to step 420 where the method 400 performs the steps 420 and 425 until step 430 determines the desired wafer of the stacked device has been reached by the opening.

Once the desired wafer of the stacked device has been reached by the opening, the method 400 proceeds to step 440. In step 440, the method 400 fills the opening with thermally conductive material to form a heat dissipation pathway using a suitable deposition process. In various embodiments, the thermally conductive material may comprise microfluidics, or some form of metal oxide. Additionally, in various embodiment, the process for filling the openings to form the heat dissipation pathways may be as described in step 240 of the method 200 in FIG. 2.

FIG. 5 is a top view of a stacked device 500 illustrating an example distribution of heat dissipation pathways 550. Additionally, the stacked device 500 comprises a pattern of electrical contacts 508 within underlying stacked wafers forming the stacked device 500. In various embodiments, the stacked device 500 may be the stacked device 100 of FIGS. 1A-1J or the stacked device 300 of FIGS. 3A-3E. Similarly, the electrical contacts 508 may be the various metal contacts (such as first metal contacts108) of FIGS. 1A-1J or the various metal contacts (such as first metal contacts 308) of FIGS. 3A-3E. Further, the heat dissipation pathways 550 may be the heat dissipation pathways 150 of FIGS. 1A-1J or the heat dissipation pathways 350 of FIGS. 3A-3E. The distribution of the heat dissipation pathways 550 may be determined to optimize heat dissipation from underlying layers and wafers of the stacked device 500. Other embodiments may distribute the heat dissipation pathways 550 differently than the embodiment illustrated in FIG. 5.

FIGS. 6-8 are flowcharts illustrating example methods of forming heat dissipation pathways in a stacked device in accordance with embodiments of this disclosure. The methods of FIGS. 6-8 may be combined with other methods and performed using suitable systems and apparatuses as described herein. Although shown in a logical order, the arrangement and numbering of the steps of FIGS. 6-8 are not intended to be limiting.

Referring to FIG. 6, step 610 of a method 600 of forming heat dissipation pathways in a stacked wafer provides a first processed wafer comprising a first substrate, a first plurality of metallization layers disposed over the first substrate, and a first dielectric layer comprising first contacts disposed over the first plurality of metallization layers and a first bonding layer. In various embodiments, the first processed wafer may be the first wafer 10 of FIG. 1A, where the first substrate is the first substrate 102, the first dielectric layer is the first dielectric layer 104, the first plurality of metallization layers are layers of the first dielectric layer 104, the first contacts are the first metal contacts 106, and the first bonding layer is the first bonding layer 108.

After, the method 600 forms a first opening through the first plurality of metallization layers, the first dielectric layer, and the first bonding layer in step 620. Forming the first opening may be as described using FIG. 1B, and the first opening may be the first opening 119. After forming the first opening, the method 600 provides a second processed wafer comprising a second substrate, a second plurality of metallization layers disposed over the second substrate, and a second dielectric layer comprising second contacts disposed over the second plurality of metallization layers and a second bonding layer in step 630. Similarly, in various embodiments, the second processed wafer may be the second wafer 12 of FIG. 1A, where the second substrate is the second substrate 112, the second dielectric layer is the second dielectric layer 114, the second contacts are the second metal contacts 116, the second bonding layer is the second bonding layer 118, and the second plurality of metallization layers are layers of the second dielectric layer 114.

After providing the second processed wafer in step 630, the method 600 may proceed to step 640. In step 640, the method 600 bonds the first processed wafer comprising the first opening with the second processed wafer to form a stacked wafer, such as the stacked device 100 illustrate in FIG. 1C. In various embodiments, the bonding may be as described for the bonding process of FIG. 1C. And after bonding to form the stacked wafer, the method 600 may fill the opening with a thermally conductive material to form a heat dissipation pathway in the stacked wafer in step 650. The filling may be as described using FIG. 1J, the thermally conductive material may be as described using FIG. 1J, and the heat dissipation pathway may be the heat dissipation pathway 150.

In alternative embodiments, the method 600 may further comprise stacking more processed wafers before filling the first opening with thermally conductive material. Those embodiments may be illustrated by the steps of the process in FIGS. 1D-1I, which may also use a thinning process to recess the first substrate or the second substrate as desired. In an embodiment, the method 600 may be an embodiment of the method 200 described using the flowchart of FIG. 2.

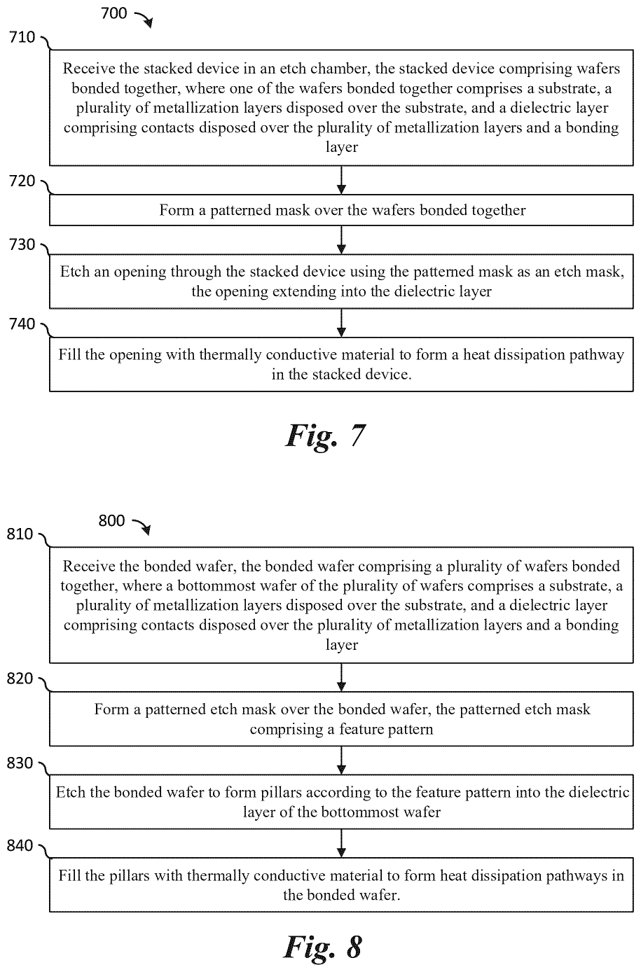

Now referring to FIG. 7, step 710 of a method 700 of forming heat dissipation pathways in a stacked device receives a stacked device in an etch chamber. In various embodiments, the stacked device comprises wafers bonded together, where one of the wafers bonded together comprises a substrate, a plurality of metallization layers disposed over the substrate, and a dielectric layer comprising contacts disposed over the plurality of metallization layers and a bonding layer. In various embodiments, the stacked device may be the stacked device 300 as illustrated in FIG. 3A, and the various layers of the stacked device may be as similarly described for the various layers of the stacked device 300. After receiving the stacked device, the method 700 may form a patterned mask over the wafers bonded together in step 720, such as described using FIGS. 3B-3C. After, in step 730, the method 700 etches an opening through the stacked device using the patterned mask as an etch mask, the opening extending into the dielectric layer. For example, step 730 may be illustrated as FIG. 3D, where the opening is the opening 341. In various embodiments, the opening may be formed using a plasma etch process, such as described above in FIG. 3D. In other embodiments, the opening may be formed using the cyclic etch process described using FIG. 3D.

And in step 740, the method 700 fills the opening with thermally conductive material to form a heat dissipation pathway in the stacked device. Step 740 may be illustrated by FIG. 3E, where the heat dissipation pathway is the heat dissipation pathway 350 of the stacked device 300. In other embodiments, multiple heat dissipation pathways may be formed in the stacked device using the method 700, such as illustrated using the stacked device 500 in FIG. 5. In various embodiments, the stacked device may be the stacked device 300 of FIGS. 3A-3E, and the method 700 may be an embodiment of the method 400 described using FIG. 4.

And now referring to FIG. 8, in step 810, a method 800 for processing a bonded wafer to form heat dissipation pathways receives the bonded wafer. In various embodiments, the bonded wafer comprises a plurality of wafers bonded together, where a bottommost wafer of the plurality of wafers comprises a substrate, a plurality of metallization layers disposed over the substrate, and a dielectric layer comprising contacts disposed over the plurality of metallization layers and a bonding layer. In various embodiments, the bonded wafer may be the stacked device 300 illustrated in FIG. 3A, and the various layers of the bonded wafer may be as similarly described for the various layers of the stacked device 300. For example, the bottommost wafer may be the first wafer 30 of FIG. 3A.

Still referring to FIG. 8, in step 820, the method 800 forms a patterned etch mask over the bonded wafer, the patterned etch mask comprising a feature pattern. In various embodiments, the patterned etch mask may be formed as described for the patterned mask 342 in FIGS. 3B-3C. In step 830, the method 800 etches the bonded wafer to form pillars according to the feature pattern into the dielectric layer of the bottommost wafer. The etching may be as described using FIG. 3D above, and the pillars may be the opening 341.

After forming the pillars in step 830, the method 800 may fill the pillars with thermally conductive material to form heat dissipation pathways in the bonded wafer in step 840. The filling may be as described using FIG. 3E above, and the heat dissipation pathways may be the heat dissipation pathway 350 of FIG. 3E or the heat dissipation pathways 550 of FIG. 5. In various embodiments, many of the steps of the method 800 may be the various steps described for the method 400 in FIG. 4. Further, in various embodiments, the bonded wafer may be the stacked device 300 of FIG. 3, where the first wafer 30 is the bottommost wafer.

Example embodiments of the invention are described below. Other embodiments can also be understood from the entirety of the specification as well as the claims filed herein.

Example 1. A method of forming a stacked wafer includes providing a first processed wafer including a first substrate, a first plurality of metallization layers disposed over the first substrate, and a first dielectric layer including first contacts disposed over the first plurality of metallization layers and a first bonding layer. The method further includes forming a first opening through the first plurality of metallization layers, the first dielectric layer, and the first bonding layer, and providing a second processed wafer including a second substrate, a second plurality of metallization layers disposed over the second substrate, and a second dielectric layer including second contacts disposed over the second plurality of metallization layers and a second bonding layer. And the method further includes bonding the first processed wafer including the first opening with the second processed wafer to form the stacked wafer, and after the bonding, filling the first opening with a thermally conductive material to form a heat dissipation pathway in the stacked wafer.

Example 2. The method of example 1, further including singulating the stacked wafer to form a plurality of stacked dies.

Example 3. The method of one of examples 1 or 2, further including thinning the first substrate to expose the first opening before filling the first opening.

Example 4. The method of one of examples 1 to 3, where the thermally conductive material includes a metal oxide, a metal nitride, a pure metal, a high-k dielectric, or a microfluidic, where the microfluidic includes water, ethylene glycol, propylene glycol, mineral oil, polyalphaolefin oil, or fluorinated oils.

Example 5. The method of one of examples 1 to 4, where the thermally conductive material is filled at a temperature between 25° C. and 400° C.

Example 6. The method of one of examples 1 to 5, where the bonding includes a hybrid bonding process.

Example 7. The method of one of examples 1 to 6, where filling the first opening includes performing a deposition process of aluminum oxide, and where forming the first opening through the first processed wafer includes performing a first plasma etching process.

Example 8. A method for forming heat dissipation pathways in a stacked device includes receiving the stacked device in an etch chamber, the stacked device including wafers bonded together, where one of the wafers bonded together includes a substrate, a plurality of metallization layers disposed over the substrate, and a dielectric layer including contacts disposed over the plurality of metallization layers and a bonding layer. The method further includes forming a patterned mask over the wafers bonded together, and etching an opening through the stacked device using the patterned mask as an etch mask, the opening extending into the dielectric layer. And the method further includes filling the opening with thermally conductive material to form a heat dissipation pathway in the stacked device.

Example 9. The method of example 8, where the thermally conductive material includes a metal oxide, a metal nitride, a pure metal, a high-k dielectric, or a microfluidic, where the microfluidic includes water, ethylene glycol, propylene glycol, mineral oil, polyalphaolefin oil, or fluorinated oils.

Example 10. The method of one of examples 8 or 9, where the thermally conductive material is filled at a temperature between 25° C. and 400° C., and where the opening includes a pillar.

Example 11. The method of one of examples 8 to 10, where the etching is a cyclic etch process, one cycle of the cyclic etch process includes exposing the stacked device to a first plasma to etch through an underlying layer of the stacked device, the underlying layer including a dielectric material, the first plasma being selective to the dielectric material of the underlying layer. And one cycle of the cyclic etch process further includes, in response to revealing the bonding layer, exposing the stacked device to a second plasma to etch through the bonding layer, the second plasma being selective to the bonding layer.

Example 12. The method of one of examples 8 to 11, where the etch chamber includes a plasma chamber of a plasma etch tool.

Example 13. The method of one of examples 8 to 12, where the thermally conductive material includes aluminum oxide, and where the filling includes a sputtering process that sputters aluminum oxide into the opening.

Example 14. The method of one of examples 8 to 13, where the thermally conductive material includes aluminum nitride, and where the filling includes an atomic layer deposition process that deposits aluminum nitride into the opening.

Example 15. The method of one of examples 8 to 14, where the thermally conductive material includes a microfluidic, and where the filling includes pouring the microfluidic into the opening.

Example 16. The method of one of examples 8 to 15, where the wafers of the stacked device include metal contacts bonded together to form electrical contacts.

Example 17. The method of one of examples 8 to 16, where the wafers of the stacked device include metallization layers, the metallization layers including dielectric layers and metallization features, the metallization features including metal lines, vias, or metal contacts.

Example 18. A method for processing a bonded wafer includes receiving the bonded wafer, the bonded wafer including a plurality of wafers bonded together, where a bottommost wafer of the plurality of wafers includes a substrate, a plurality of metallization layers disposed over the substrate, and a dielectric layer including contacts disposed over the plurality of metallization layers and a bonding layer. The method further includes forming a patterned etch mask over the bonded wafer, the patterned etch mask including a feature pattern, and etching the bonded wafer to form openings according to the feature pattern into the dielectric layer of the bottommost wafer. And the method further includes filling the openings with thermally conductive material to form heat dissipation pathways in the bonded wafer.

Example 19. The method of example 18, where the thermally conductive material includes a metal oxide, a metal nitride, a pure metal, a high-k dielectric, or a microfluidic, where the microfluidic includes water, ethylene glycol, propylene glycol, mineral oil, polyalphaolefin oil, or fluorinated oils.

Example 20. The method of one of examples 18 or 19, where the thermally conductive material is filled at a temperature between 25° C. and 400° C.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a stacked wafer, the method comprising:
providing a first processed wafer comprising a first substrate, a first plurality of metallization layers disposed over the first substrate, and a first dielectric layer comprising first contacts disposed over the first plurality of metallization layers and a first bonding layer;
forming a first opening through the first plurality of metallization layers, the first dielectric layer, and the first bonding layer;
providing a second processed wafer comprising a second substrate, a second plurality of metallization layers disposed over the second substrate, and a second dielectric layer comprising second contacts disposed over the second plurality of metallization layers and a second bonding layer;
bonding the first processed wafer comprising the first opening with the second processed wafer to form the stacked wafer; and
after the bonding, filling the first opening with a thermally conductive material to form a heat dissipation pathway in the stacked wafer.

2. The method of claim 1, further comprising singulating the stacked wafer to form a plurality of stacked dies.

3. The method of claim 1, further comprising thinning the first substrate to expose the first opening before filling the first opening.

4. The method of claim 1, wherein the thermally conductive material comprises a metal oxide, a metal nitride, a pure metal, a high-k dielectric, or a microfluidic, wherein the microfluidic comprises water, ethylene glycol, propylene glycol, mineral oil, polyalphaolefin oil, or fluorinated oils.

5. The method of claim 1, wherein the thermally conductive material is filled at a temperature between 25° C. and 400° C.

6. The method of claim 1, wherein the bonding comprises a hybrid bonding process.

7. The method of claim 1, wherein filling the first opening comprises performing a deposition process of aluminum oxide, and wherein forming the first opening through the first processed wafer comprises performing a first plasma etching process.

8. A method for forming heat dissipation pathways in a stacked device, the method comprising:
receiving the stacked device in an etch chamber, the stacked device comprising wafers bonded together, wherein one of the wafers bonded together comprises a substrate, a plurality of metallization layers disposed over the substrate, and a dielectric layer comprising contacts disposed over the plurality of metallization layers and a bonding layer;
forming a patterned mask over the wafers bonded together;
etching an opening through the stacked device using the patterned mask as an etch mask, the opening extending into the dielectric layer; and
filling the opening with thermally conductive material to form a heat dissipation pathway in the stacked device.

9. The method of claim 8, wherein the thermally conductive material comprises a metal oxide, a metal nitride, a pure metal, a high-k dielectric, or a microfluidic, wherein the microfluidic comprises water, ethylene glycol, propylene glycol, mineral oil, polyalphaolefin oil, or fluorinated oils.

10. The method of claim 8, wherein the thermally conductive material is filled at a temperature between 25° C. and 400° C., and wherein the opening comprises a pillar.

11. The method of claim 8, wherein the etching is a cyclic etch process, one cycle of the cyclic etch process comprising:
exposing the stacked device to a first plasma to etch through an underlying layer of the stacked device, the underlying layer comprising a dielectric material, the first plasma being selective to the dielectric material of the underlying layer; and
in response to revealing the bonding layer, exposing the stacked device to a second plasma to etch through the bonding layer, the second plasma being selective to the bonding layer.

12. The method of claim 8, wherein the etch chamber comprises a plasma chamber of a plasma etch tool.

13. The method of claim 8, wherein the thermally conductive material comprises aluminum oxide, and wherein the filling comprises a sputtering process that sputters aluminum oxide into the opening.

14. The method of claim 8, wherein the thermally conductive material comprises aluminum nitride, and wherein the filling comprises an atomic layer deposition process that deposits aluminum nitride into the opening.

15. The method of claim 8, wherein the thermally conductive material comprises a microfluidic, and wherein the filling comprises pouring the microfluidic into the opening.

16. The method of claim 8, wherein the wafers of the stacked device comprise metal contacts bonded together to form electrical contacts.

17. The method of claim 8, wherein the wafers of the stacked device comprise metallization layers, the metallization layers comprising dielectric layers and metallization features, the metallization features comprising metal lines, vias, or metal contacts.

18. A method for processing a bonded wafer, the method comprising:
receiving the bonded wafer, the bonded wafer comprising a plurality of wafers bonded together, wherein a bottommost wafer of the plurality of wafers comprises a substrate, a plurality of metallization layers disposed over the substrate, and a dielectric layer comprising contacts disposed over the plurality of metallization layers and a bonding layer;
forming a patterned etch mask over the bonded wafer, the patterned etch mask comprising a feature pattern;
etching the bonded wafer to form openings according to the feature pattern into the dielectric layer of the bottommost wafer; and
filling the openings with thermally conductive material to form heat dissipation pathways in the bonded wafer.

19. The method of claim 18, wherein the thermally conductive material comprises a metal oxide, a metal nitride, a pure metal, a high-k dielectric, or a microfluidic, wherein the microfluidic comprises water, ethylene glycol, propylene glycol, mineral oil, polyalphaolefin oil, or fluorinated oils.

20. The method of claim 18, wherein the thermally conductive material is filled at a temperature between 25° C. and 400° C.
